(19) United States
(12) Patent Application Publication
(10) Pub. No.: US 2025/0160179 A1
(43) Pub. Date: May 15, 2025

(54) DISPLAY DEVICE

(71) Applicant: Samsung Display Co., LTD., Yongin-si (KR)

(72) Inventors: Soo Im JEONG, Yongin-si (KR); Ju Won LEE, Yongin-si (KR); Kwang Rok MUN, Yongin-si (KR); Soon Mi CHOI, Yongin-si (KR)

(73) Assignee: Samsung Display Co., LTD., Yongin-si (KR)

(21) Appl. No.: 18/738,312

(22) Filed: Jun. 10, 2024

(30) Foreign Application Priority Data
Nov. 14, 2023 (KR) 10-2023-0157064

(51) Int. Cl. H10K 59/80; H10K 59/38

(52) U.S. Cl. CPC H10K 59/874; H10K 59/38; H10K 59/8723; H10K 59/873

(57) ABSTRACT

A display device includes a substrate comprising a display area and a non-display area, a light emitting element layer disposed on the display area of the substrate, a counter substrate facing the substrate, a low refractive layer disposed on a surface of the counter substrate, a first capping layer disposed on a surface of the low refractive layer, a second capping layer disposed on a surface of the first capping layer, a spacer layer disposed on a surface of the second capping layer, a first coupling member between the substrate and the counter substrate, and coupling the substrate to the counter substrate, and a second coupling member disposed on side surfaces of the substrate and the counter substrate, and coupling the substrate to the counter substrate. The first coupling member extends to the spacer layer. The first coupling member contains a first moisture absorbent.

### CROSS-REFERENCE TO RELATED APPLICATION(S)

This application claims priority to and benefits of Korean Patent Application No. 10-2023-0157064 under 35 U.S.C. 119, filed on Nov. 14, 2023 in the Korean Intellectual Property Office, the entire contents of which are herein incorporated by reference.

### BACKGROUND

### 1. Technical Field

The disclosure relates to a display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device include an organic light emitting display device composed of organic light emitting elements, an inorganic light emitting display device composed of inorganic light emitting elements such as inorganic semiconductors, and a micro light emitting display device composed of micro light emitting elements.

The organic light emitting element may include two opposing electrodes, and a light emitting layer disposed between the two opposing electrodes. The light emitting layer receives electrons and holes from the two electrodes and recombines them to generate excitons, and the generated excitons change from an excited state to a ground state, thereby emitting light.

The organic light emitting display device including organic light emitting elements is attracting attention as a next-generation display device because of being able to meet the high display quality requirements such as wide viewing angle, high brightness and contrast, and quick response speed as well as being able to be made having a low power consumption, lightweight, and thin due to no necessity of a power source such as a backlight unit.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device capable of decreasing defects in the display device by preventing moisture permeation from the outside.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, a display device may include a substrate comprising a display area and a non-display area, a light emitting element layer disposed on the display area of the substrate, a counter substrate facing the substrate, a low refractive layer disposed on a surface of the counter substrate, a first capping layer disposed on a surface of the low refractive layer, a second capping layer disposed on a surface of the first capping layer, a spacer layer disposed on a surface of the second capping layer, a first coupling member between the substrate and the counter substrate, and coupling the substrate to the counter substrate, and a second coupling member disposed on side surfaces of the substrate and the counter substrate, and coupling the substrate to the counter substrate. The first coupling member may extend to the spacer layer. The first coupling member may include a first moisture absorbent.

In an embodiment, the first coupling member may surround the display area in plan view.

In an embodiment, the first moisture absorbent may be included in an amount of 20% to 50% by weight with respect to a total weight of the first coupling member.

In an embodiment, the first coupling member may further include spacer particles.

In an embodiment, the second coupling member may be spaced apart from the first coupling member. The second coupling member may surround the first coupling member in plan view.

In an embodiment, the second coupling member may include a second moisture absorbent.

In an embodiment, the second moisture absorbent may be included in an amount of 20% to 50% by weight with respect to a total weight of the second coupling member.

In an embodiment, the second coupling member may extend to a side surface of each of the low refractive layer, the first capping layer, the second capping layer, and the spacer layer.

In an embodiment, at least one of the first capping layer and the second capping layer may include silicon oxynitride represented by Chemical Formula 1:

SiₓO_{y}N_{z} (30≤x≤40, 1≤y≤5, and 55≤z≤70), [Chemical Formula 1]
where the unit is atomic %.

In an embodiment, the display device may further include a color filter layer between the counter substrate and the low refractive layer. The color filter layer may include a first color filter disposed on a surface of the counter substrate, a second color filter disposed on a surface of the first color filter, and a third color filter disposed on a surface of the second color filter. The second coupling member may extend to a side surface of the color filter layer.

In an embodiment, the display device may further include a wavelength conversion layer between the first capping layer and the second capping layer. The wavelength conversion layer may include a first light transmitting member which intactly transmits first color light emitted from the light emitting element layer, a second light transmitting member which converts the first color light emitted from the light emitting element layer into second color light, and a third light transmitting member which converts the first color light emitted from the light emitting element layer into third color light.

In an embodiment, the display device may further include a thin film encapsulation layer disposed on the light emitting element layer. The thin film encapsulation layer may include a lower inorganic layer overlapping the light emitting element layer, an organic layer disposed on the lower inorganic layer, and an upper inorganic layer disposed on the organic layer.

In an embodiment, the display device may further include a filling layer between the thin film encapsulation layer and the second capping layer. The filling layer may extend to the first coupling member.

According to an aspect of the disclosure, a display device may include a substrate, a light emitting element layer disposed on the substrate, a counter substrate facing the substrate, a low refractive layer disposed on a surface of the counter substrate, a first capping layer disposed on a surface of the low refractive layer, a second capping layer disposed on a surface of the first capping layer, a spacer layer disposed on a surface of the second capping layer, a first coupling member between the substrate and the counter substrate, and coupling the substrate to the counter substrate, and a second coupling member disposed on side surfaces of the substrate and the counter substrate, and coupling the substrate to the counter substrate. At least one of the first capping layer and the second capping layer may include silicon oxynitride represented by Chemical Formula 1:

SiₓO_{y}N_{z} (30≤x≤40, 1≤y≤5, and 55≤z≤70), [Chemical Formula 1]
where the unit is atomic %.

In an embodiment, the first coupling member may include a first moisture absorbent, and the first moisture absorbent may be included in an amount of 20% to 50% by weight with respect to a total weight of the first coupling member.

In an embodiment, the second coupling member may include a second moisture absorbent, and the second moisture absorbent may be included in an amount of 20% to 50% by weight with respect to a total weight of the second coupling member.

In an embodiment, the second coupling member may be spaced apart from the first coupling member. The second coupling member may surround the first coupling member in plan view.

In an embodiment, pores may be between the first coupling member and the second coupling member.

In an embodiment, the spacer layer may include an organic material. The first coupling member may extend to the spacer layer.

In an embodiment, the low refractive layer may include an organic material. The second coupling member may extend to a side surface of the low refractive layer.

The display device according to an embodiment may include a moisture absorbent in a first coupling member, thereby preventing moisture permeation caused by a spacer layer, and thus preventing defects such as delamination or oxidation of a thin film encapsulation layer.

Further, the display device according to an embodiment may further include a moisture absorbent in a second coupling member, thereby preventing moisture permeation caused by a low refractive layer, and therefore preventing delamination defects in a color filter layer.

Further, the display device according to an embodiment may prevent moisture permeation by adjusting an atomic ratio of a first capping layer that covers the low refractive layer.

However, effects according to the embodiments of the disclosure are not limited to those mentioned above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment;

FIG. 2 is a schematic diagram showing wires included in a display device according to an embodiment;

FIG. 3 is a schematic diagram of an equivalent circuit of a sub-pixel according to an embodiment;

FIG. 4 is a schematic cross-sectional view illustrating a display device according to an embodiment;

FIG. 5 is a schematic cross-sectional view illustrating a display area of a display device according to an embodiment;

FIG. 6 is a schematic cross-sectional view illustrating a display device according to an embodiment;

FIG. 7 is a schematic cross-sectional view illustrating a non-display area of a display device according to an embodiment;

FIG. 8 is a schematic plan view showing arrangement of a first coupling member of a display device according to an embodiment;

FIG. 9 is a schematic cross-sectional view showing a moisture permeation path in a display device;

FIG. 10 is a schematic cross-sectional view of a display device according to another embodiment;

FIG. 11 is a schematic cross-sectional view showing a moisture permeation path of a display device;

FIG. 12 is a schematic cross-sectional view showing a display device according to still another embodiment;

FIG. 13 is a schematic graph showing the OH contents of the spacer layer and the first coupling member according to Experimental Example 1; and

FIG. 14 is a schematic graph showing the D contents of D₂O in the low refractive layer and the first capping layer according to Experimental Example 2.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

It will also be understood that when a layer is referred to as being “on” another layer or substrate, it can be directly on the other layer or substrate, or intervening layers may also be present. The same reference numbers indicate the same components throughout the specification.

As used herein, the singular forms, “a,” “an,” and “the” are intended to include the plural forms as well, unless the context clearly indicates otherwise.

The terms “comprises,” “comprising,” “contain,” “containing,” “includes,” “including,” “has,” “have,” “having,” and the like when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or “to not overlap” another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

“About,” “approximately,” and “substantially” as used herein are inclusive of the stated value and mean within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Each of the features of the various embodiments of the disclosure may be combined or combined with each other, in part or in whole, and technically various interlocking and driving are possible. Each embodiment may be implemented independently of each other or may be implemented together in an association.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

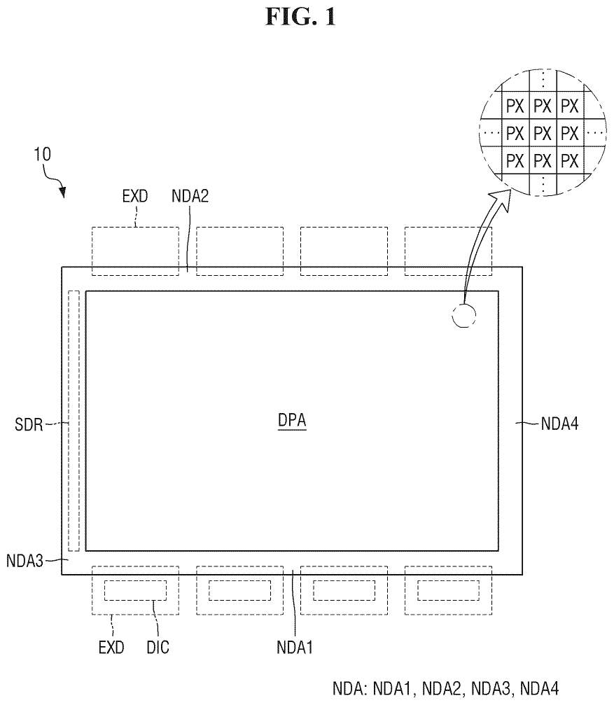

FIG. 1 is a schematic plan view of a display device according to an embodiment.

Referring to FIG. 1, a display device 10 according to an embodiment may be applied to a smartphone, a mobile phone, a tablet PC, a personal digital assistant (PDA), a portable multimedia player (PMP), a television, a game machine, a wristwatch-type electronic device, a head-mounted display, a monitor of a personal computer, a laptop computer, a car navigation system, a car's dashboard, a digital camera, a camcorder, an external billboard, an electronic billboard, a medical device, an inspection device, various household appliances such as a refrigerator and a washing machine, or an Internet-of-Things device. Herein, a television (TV) is described as an example of the display device 10, and the TV may have a high resolution or an ultra high resolution such as HD, UHD, 4K and 8K.

In addition, the display device 10 according to an embodiment may be classified into various types according to a display method. For example, the display device 10 may be classified into an organic light emitting display (OLED) device, an inorganic light emitting display (inorganic EL) device, a quantum dot light emitting display (QED) device, a micro-LED display device, a nano-LED display device, a plasma display device (PDP), a field emission display (FED) device, a cathode ray tube (CRT) display device, a liquid crystal display (LCD) device, an electrophoretic display (EPD) device, and the like. Hereinafter, an organic light emitting display device and an inorganic light emitting display device will be described as an example of the display device 10, and display devices applied to the embodiment will be simply referred to as a display device unless special distinction is required. However, the embodiment is not limited to the organic light emitting display device or the inorganic light emitting display device, and other display devices mentioned above or otherwise may be applied.

The display device 10 according to an embodiment may have a quadrate shape, e.g., a rectangular shape in plan view. In a case where the display device 10 is a television, the display device 10 may be disposed such that its long side extends in a horizontal direction. However, the disclosure is not limited thereto, and the long side of the display device 10 may extend in a vertical direction. In another embodiment, the display device 10 may be installed to be rotatable such that its long side is variably positioned to extend in the horizontal or vertical direction.

The display device 10 may include a display area DPA and a non-display area NDA. The display area DPA may be an active area in which an image is displayed. The display area DPA may have a rectangular shape in plan view similar to the overall shape of the display device 10, but the disclosure is not limited thereto.

The display area DPA may include pixels PX. The pixels PX may be arranged in a matrix. The shape of each pixel PX may be rectangular or square in plan view. However, without being limited thereto, each pixel PX may have a rhombic shape of which each side is inclined with respect to one side direction of the display device 10. The pixels PX may include multiple color pixels PX. For example, the pixels PX may include, a first color pixel PX of red, a second color pixel PX of green, and a third color pixel PX of blue, although not limited thereto. Each color pixel PX may be alternately arranged in a stripe type arrangement or a PenTile™ type arrangement.

The non-display area NDA may be disposed around the display area DPA. The non-display area NDA may completely or partially surround the display area DPA. The display area DPA may have a rectangular shape, and the non-display area NDA may be disposed adjacent to four sides of the display area DPA. The non-display area NDA may form a bezel of the display device 10.

In the non-display area NDA, a driving circuit or a driving element for driving the display area DPA may be disposed. In an embodiment, in a first non-display area NDA1 disposed adjacent to a first long side (lower side in FIG. 1) of the display device 10 and a second non-display area NDA2 disposed adjacent to a second long side (upper side in FIG. 1) of the display device 10, pad portions may be provided on a display substrate of the display device 10, and external devices EXD may be mounted on pad electrodes of the pad portions. The external devices EXD may include, e.g., a connection film, a printed circuit board, a driver integrated circuit (DIC), a connector, a wiring connection film and the like. A scan driver SDR directly formed on the display substrate of the display device 10 may be provided in a third non-display area NDA3 disposed adjacent to a first short side (left side in FIG. 1) of the display device 10. However, the disclosure is not limited thereto, and the scan driver SDR may be disposed on a second short side (right side in FIG. 1) of the display device 10.

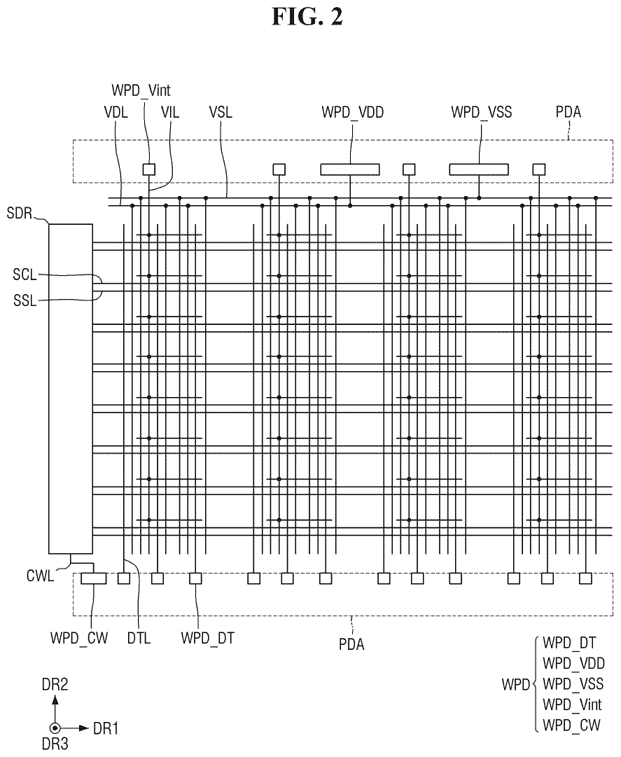

FIG. 2 is a schematic diagram showing wires included in a display device according to an embodiment.

Referring to FIG. 2, the display device 10 may include wires. The wires may include a scan line SCL, a sensing line SSL, a data line DTL, an initialization voltage line VIL, a first voltage line VDL, a second voltage line VSL, and the like. Although not shown in the drawing, other wires may be further provided in the display device 10.

The scan line SCL and the sensing line SSL may extend in a first direction DR1. The scan line SCL and the sensing line SSL may be connected to the scan driver SDR. The scan driver SDR may include a driving circuit. The scan driver SDR may be arranged on one side of the display area DPA in the first direction DR1, but embodiments are not limited thereto. The scan driver SDR may be connected to a signal connection line CWL, and at least one end of the signal connection line CWL may form a pad WPD_CW on a pad area PDA of the non-display area to be connected to the external device.

The term “connected” as used herein may mean not only that one member is connected to another member through a physical contact, but also that one member is connected to another member through yet another member. This may also be understood as one part and the other part as integral elements are connected into an integrated element via another element. Furthermore, if one element is connected to another element, this may be construed as a meaning including an electrical connection via another element in addition to a direct connection in physical contact.

The data line DTL and the initialization voltage line VIL may extend in a second direction DR2 intersecting the first direction DR1. The initialization voltage line VIL may further include, in addition to a portion extending in the second direction DR2, a portion branched in the first direction DR1 therefrom. The first voltage line VDL and the second voltage line VSL may also include a portion extending in the second direction DR2 and a portion connected thereto to extend in the first direction DR1. The first voltage line VDL and the second voltage line VSL may have a mesh structure, but are not limited thereto. Although not shown in the drawing, each pixel PX of the display device 10 may be connected to at least one data line DTL, the initialization voltage line VIL, the first voltage line VDL, and the second voltage line VSL.

The data line DTL, the initialization voltage line VIL, the first voltage line VDL, and the second voltage line VSL may be electrically connected to at least one wiring pad WPD. Each wiring pad WPD may be disposed in the pad area PDA. In an embodiment, a wiring pad WPD_DT (hereinafter, referred to as “data pad”) of the data line DTL may be disposed in the pad area PDA located on one side of the display area DPA in the second direction DR2. Further, a wiring pad WPD_Vint (hereinafter, referred to as “initialization voltage pad”) of the initialization voltage line VIL, a wiring pad WPD_VDD (hereinafter, referred to as “first power pad”) of the first voltage line VDL, and a wiring pad WPD_VSS (hereinafter, referred to as “second power pad”) of the second voltage line VSL may be disposed in the pad area PDA located on the other side of the display area DPA in the second direction DR2. As another example, the data pad WPD_DT, the initialization voltage pad WPD_Vint, the first power pad WPD_VDD, and the second power pad WPD_VSS may all be disposed in the same area, e.g., in the non-display area NDA located above the display area DPA. The external devices EXD may be mounted on the wiring pads WPD. The external devices EXD may be mounted on the wiring pads WPD by applying an anisotropic conductive film, ultrasonic bonding or the like.

Each pixel PX or sub-pixel of the display device 10 may include a pixel driving circuit. The above-described wirings may pass through each pixel PX or the vicinity thereof to apply a driving signal to each pixel driving circuit. The pixel driving circuit may include transistors and capacitors. The number of the transistors and the capacitors of each pixel driving circuit may be variously modified. According to an embodiment, in each sub-pixel of the display device 10, the pixel driving circuit may have a 3T1C structure including three transistors and one capacitor. Hereinafter, the pixel driving circuit of the 3T1C structure will be described as an example, but the disclosure is not limited thereto, and various other modified pixel PX structures such as a 2T1C structure, a 7T1C structure, and a 6T1C structure may be applied.

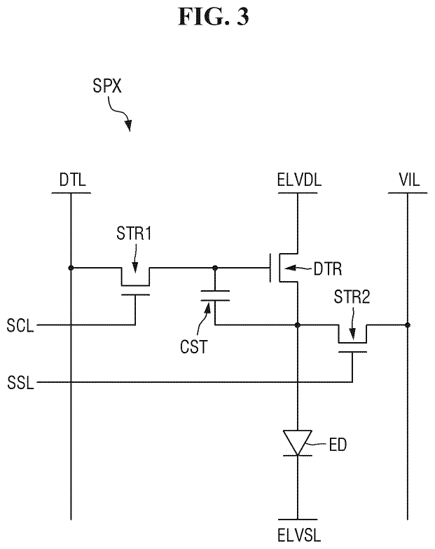

FIG. 3 is a schematic diagram of an equivalent circuit of a sub-pixel according to an embodiment.

Referring to FIG. 3, each sub-pixel SPX of the display device 10 according to an embodiment may include three transistors DTR, STR1 and STR2 and one storage capacitor CST in addition to a light emitting element ED.

The light emitting element ED may emit light according to a current supplied through a driving transistor DTR. The light emitting element ED may be implemented as an inorganic light emitting diode, an organic light emitting diode, a micro light emitting diode, or a nano light emitting diode.

A first electrode (i.e., anode electrode) of the light emitting element ED may be connected to a source electrode of the driving transistor DTR, and a second electrode (i.e., cathode electrode) of the light emitting element ED may be connected to a second power line ELVSL to which a low potential voltage (second source voltage) lower than a high potential voltage (first source voltage) of a first power line ELVDL is supplied.

The driving transistor DTR may adjust a current flowing from the first power line ELVDL, to which the first source voltage is applied, to the light emitting element ED according to a voltage difference between a gate electrode and the source electrode. The gate electrode of the driving transistor DTR may be connected to the first electrode of a first transistor STR1, the source electrode thereof may be connected to the first electrode of the light emitting element ED, and the drain electrode thereof may be connected to the first power line ELVDL to which the first power voltage is applied.

The first transistor STR1 may be turned on by the scan signal of a scan line SCL to connect the data line DTL to the gate electrode of the driving transistor DTR. The gate electrode of the first transistor STR1 may be connected to the scan line SCL, the first electrode thereof may be connected to the gate electrode of the driving transistor DTR, and the second electrode thereof may be connected to the data line DTL.

A second transistor STR2 may be turned on by the sensing signal of a sensing line SSL to connect an initialization voltage line VIL to the source electrode of the driving transistor DTR. The gate electrode of the second transistor STR2 may be connected to the sensing line SSL, the first electrode thereof may be connected to the initialization voltage line VIL, and the second electrode thereof may be connected to the source electrode of the driving transistor DTR.

In an embodiment, the first electrode of each of the first and second transistors STR1 and STR2 may be a source electrode and the second electrode thereof may be a drain electrode, but the disclosure is not limited thereto, and may be vice versa.

The capacitor CST may be formed between the gate electrode and the source electrode of the driving transistor DTR. The storage capacitor CST may store a difference voltage between a gate voltage and a power voltage of the driving transistor DTR.

The driving transistor DTR, the first transistor STR1, and the second transistor STR2 may be formed as thin film transistors. Further, in the description of FIG. 3, it is assumed that the driving transistor DTR, the first switching transistor STR1, and the second switching transistor STR2 are N-type metal oxide semiconductor field effect transistors (MOSFETs), but the disclosure is not limited thereto. For example, the driving transistor DTR, the first switching transistor STR1, and the second switching transistor STR2 may be P-type MOSFETs, or some of the driving transistor DTR, the first switching transistor STR1, and the second switching transistor STR2 may be N-type MOSFETs, while others may be P-type MOSFETs.

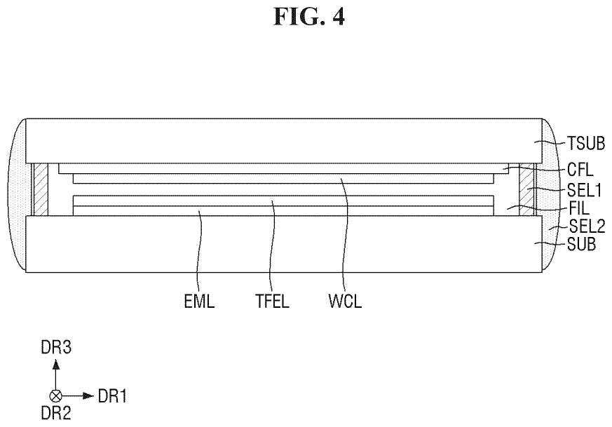

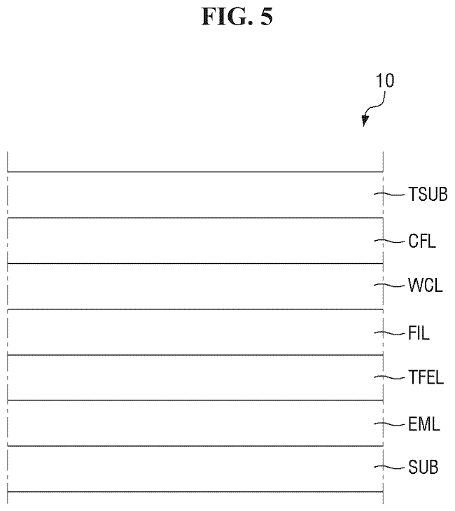

FIG. 4 is a schematic cross-sectional view illustrating a display device according to an embodiment. FIG. 5 is a schematic cross-sectional view illustrating a display area of a display device according to an embodiment.

Referring to FIGS. 4 and 5, the display device 10 according to an embodiment may include a substrate SUB, a light emitting element layer EML, a thin film encapsulation layer TFEL, a filling layer FIL, a wavelength conversion layer WCL, a color filter layer CFL, a counter substrate TSUB, a first coupling member SEL1, and a second coupling member SEL2.

The substrate SUB may be an insulating substrate. The substrate SUB may include a transparent material. For example, the substrate SUB may include a transparent insulating material such as glass, quartz, or the like. The substrate SUB may be a rigid substrate. Further, the substrate SUB is not limited thereto. The substrate SUB may include plastic such as polyimide or the like, and may have a flexible property such that it can be twisted, bent, folded, or rolled.

The light emitting element layer EML may be disposed on the substrate SUB. The light emitting element layer EML may include switching elements and light emitting elements ED disposed in each sub-pixel. The switching elements may drive the light emitting elements ED so that the light emitting elements ED may emit light.

The thin film encapsulation layer TFEL may be disposed on the light emitting element layer EML. The thin film encapsulation layer TFEL may include an organic layer disposed between inorganic layers and may protect the light emitting element layer EML from external moisture and oxygen.

The counter substrate TSUB may be disposed to face the substrate SUB. The counter substrate TSUB may encapsulate the light emitting element layer EML together with the substrate SUB. The counter substrate TSUB may include a transparent material. For example, the counter substrate TSUB may include a transparent insulating material such as glass, quartz, or the like.

The color filter layer CFL may be disposed on one surface of the counter substrate TSUB. The color filter layer CFL may filter light incident from the outside to reduce reflection of external light and improve the color characteristics of light emitted through the wavelength conversion layer WCL.

The wavelength conversion layer WCL may be disposed on one surface of the color filter layer CFL. The wavelength conversion layer WCL may convert the wavelength of light emitted from the light emitting element layer EML to emit red light, green light, and blue light.

The filling layer FIL may be disposed between the substrate SUB and the counter substrate TSUB. The filling layer FIL may be filled between the substrate SUB and the counter substrate TSUB to protect the display area of the display device 10.

The substrate SUB and the counter substrate TSUB may be coupled to each other by the first coupling member SELL. The first coupling member SEL1 may encapsulate the light emitting element layer EML by coupling the substrate SUB and the counter substrate TSUB to each other. The first coupling member SEL1 may be disposed in the non-display area to surround the display area of the display device 10.

The second coupling member SEL2 may be disposed on the side surfaces of the substrate SUB and the counter substrate TSUB. The second coupling member SEL2 may seal the side surface of the display device 10 to prevent moisture permeation.

At least one of the first coupling member SEL1 and the second coupling member SEL2 may include a moisture absorbent material such as metal oxide. The moisture absorbent material may be a material that absorbs moisture and may prevent defects in the display device 10 by absorbing moisture permeating from the outside.

Hereinafter, configurations of a display device according to an embodiment will be described in detail with reference to other drawings.

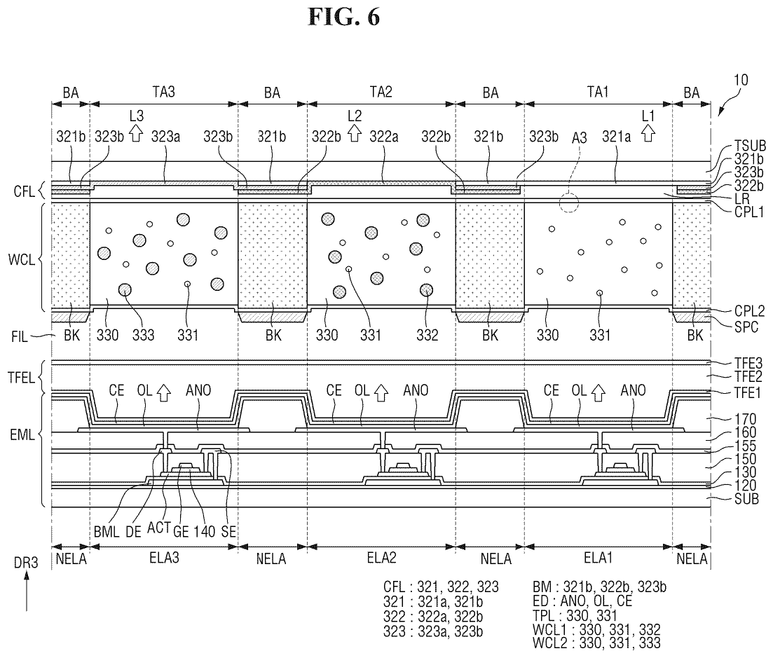

FIG. 6 is a schematic cross-sectional view illustrating a display device according to an embodiment. FIG. 6 shows a portion of the display area of the display device.

Referring to FIG. 6 in conjunction with FIG. 5, the light emitting element layer EML may be disposed on the substrate SUB. The light emitting element layer EML may include a buffer layer 120, a lower metal layer BML, a first insulating layer 130, a semiconductor layer ACT, a gate electrode GE, a gate insulating layer GI, a second insulating layer 150, a source electrode SE, a drain electrode DE, a third insulating layer 155, a fourth insulating layer 160, a light emitting element ED, and a pixel defining layer 170.

The buffer layer 120 may be disposed on the substrate SUB. The buffer layer 120 may serve to block foreign matter or moisture penetrating through the substrate SUB to the element disposed on the buffer layer 120.

The buffer layer 120 may include an inorganic material such as SiO₂, SiNₓ, or SiON, and may be formed as a single layer or multilayer, but embodiments are not limited thereto.

The lower metal layer BML may be disposed on the buffer layer 120. The lower metal layer BML may block external light or light emitted from a light emitting element to be described later from being introduced into the semiconductor layer ACT. Accordingly, it is possible to prevent or reduce the occurrence of leakage current due to light in the thin film transistor to be described later.

The lower metal layer BML may be made of a material that blocks light and has conductivity. In some embodiments, the lower metal layer BML may include a single material of metal such as silver (Ag), nickel (Ni), gold (Au), platinum (Pt), aluminum (Al), copper (Cu), molybdenum (Mo), titanium (Ti), or neodymium (Nd), or an alloy thereof. In some embodiments, the lower metal layer BML may have a single-layer or multilayer structure. For example, in case that the lower metal layer BML has a multilayer structure, it may have a stacked structure of titanium (Ti)/copper (Cu)/indium tin oxide (ITO), or a stacked structure of titanium (Ti)/copper (Cu)/aluminum oxide (Al₂O₃), but embodiments are not limited thereto.

In some embodiments, multiple lower metal layers BML may be provided to respectively correspond to the semiconductor layers ACT and may overlap the semiconductor layers ACT. In some embodiments, the width of the lower metal layer BML may be greater than the width of the semiconductor layer ACT.

In some embodiments, the lower metal layer BML may be a portion of a data line, a power line, a wire that electrically connects the thin film transistor (not illustrated in the drawing) and the thin film transistor (GE, ACT, DE, and SE in FIG. 6) illustrated in the drawing to each other, and the like. In some embodiments, the lower metal layer BML may be made of a material having a lower resistance than the resistance of the source electrode SE and the drain electrode DE.

The first insulating layer 130 may be disposed on the lower metal layer BML. The first insulating layer 130 may serve to electrically insulate the lower metal layer BML from the semiconductor layer ACT. The first insulating layer 130 may cover the lower metal layer BML.

The first insulating layer 130 may include an inorganic material such as SiO₂, SiNₓ, SiON, Al₂O₃, TiO₂, Ta₂O, HfO₂, or ZrO₂, but embodiments are not limited thereto.

The semiconductor layer ACT may be disposed on the first insulating layer 130. The semiconductor layer ACT may be disposed to correspond to each of a first emission area ELA1, a second emission area ELA2, and a third emission area ELA3 in the display area DPA. Further, the semiconductor layer ACT may be disposed to overlap the lower metal layer BML, thereby suppressing generation of a photocurrent in the semiconductor layer ACT.

The semiconductor layer ACT may include an oxide semiconductor. In some embodiments, the semiconductor layer ACT may be formed of a Zn oxide-based material, e.g., Zn oxide, In—Zn oxide, or Ga—In—Zn oxide, and may be an In—Ga—Zn—O (IGZO) semiconductor containing a metal such as indium (In) or gallium (Ga), but embodiments are not limited thereto. For example, the semiconductor layer ACT may include amorphous silicon or polysilicon.

The gate electrode GE may be disposed on the semiconductor layer ACT. The gate electrode GE may be disposed to overlap the semiconductor layer ACT in the display area DPA. In some embodiments, the width of the gate electrode GE may be narrower than the width of the semiconductor layer ACT, but embodiments are not limited thereto.

The gate electrode GE may include one or more materials of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) in consideration of adhesion with an adjacent layer, surface flatness of a stacked layer, processability, and the like, and may be formed into a single layer or multiple layers, but embodiments are not limited thereto.

The gate insulating layer 140 may be disposed between the semiconductor layer ACT and the gate electrode GE. The gate insulating layer 140 may insulate the semiconductor layer ACT from the gate electrode GE. In some embodiments, the gate insulating layer 140 may not be constituted with a single layer disposed on one side of the first substrate 110 in the third direction DR3 but be constituted with a partially patterned shape, and the width of the gate insulating layer 140 may be narrower than the width of the semiconductor layer ACT and be wider than the width of the gate electrode GE, but embodiments are not limited thereto.

The gate insulating layer 140 may include an inorganic material. For example, the gate insulating layer 140 may include the inorganic material discussed in the description of the first insulating layer 130.

The second insulating layer 150 may be disposed on the gate insulating layer 140 to cover the semiconductor layer ACT and the gate electrode GE. In some embodiments, the second insulating layer 150 may function as a planarization layer providing a flat surface.

The second insulating layer 150 may include an organic material. In some embodiments, the second insulating layer 150 may include at least one of photo acryl (PAC), polystyrene, polymethylmethacrylate (PMMA), polyacrylonitrile (PAN), polyamide, polyimide, polyarylether, heterocyclic polymer, parylene, fluorine-based polymer, epoxy resin, benzocyclobutene-based resin, siloxane-based resin, and silane resin, but the disclosure is not limited thereto.

In some embodiments, the second insulating layer 150 may include an inorganic material. For example, the second insulating layer 150 may include the inorganic material discussed in the description of the first insulating layer 130.

The source electrode SE and the drain electrode DE may be spaced apart from each other and disposed on the second insulating layer 150. The source electrode SE and the drain electrode DE may be connected to the semiconductor layer ACT through contact holes penetrating the second insulating layer 150, respectively. The source electrode SE may penetrate the first insulating layer 130 as well as the second insulating layer 150 and may be connected to the lower metal layer BML. In case that the lower metal layer BML is a portion of a wire that transmits a signal, a voltage, and the like, the source electrode SE may be connected and electrically coupled to the lower metal layer BML to receive a transmitted voltage and the like provided to the wire. In another embodiment, in case that the lower metal layer BML is a floating pattern rather than a separate wire, a voltage and the like provided to the source electrode SE may be transmitted to the lower metal layer BML and the like.

The source electrode SE and the drain electrode DE may include aluminum (Al), copper (Cu), titanium (Ti), and the like, and may be formed as a multilayer or a single layer. In some embodiments, the source electrode SE and the drain electrode DE may have a multilayer structure of Ti/Al/Ti, but are not limited thereto.

The semiconductor layer ACT, the gate electrode GE, the source electrode SE, and the drain electrode DE described above may form a thin film transistor that is a switching element. In some embodiments, the thin film transistor may be positioned in each of the first emission area ELA1, the second emission area ELA2, and the third emission area ELA3. In some embodiments, a portion of the thin film transistor may be positioned in a non-emission area NELA.

The third insulating layer 155 may be disposed on the second insulating layer 150 to cover the thin film transistor. In some embodiments, the third insulating layer 155 may be a passivation layer.

In some embodiments, the third insulating layer 155 may include an inorganic material. For example, the third insulating layer 155 may include the inorganic material discussed in the description of the first insulating layer 130.

The fourth insulating layer 160 may be disposed on the third insulating layer 155 and cover the third insulating layer 155. In some embodiments, the fourth insulating layer 160 may be a planarization layer.

The fourth insulating layer 160 may be made of an organic material. In some embodiments, the fourth insulating layer 160 may include an acrylic resin, an epoxy resin, an imide resin, an ester resin, and the like, or may include a photosensitive organic material, but embodiments are not limited thereto.

Anode electrodes ANO may be disposed on the fourth insulating layer 160 in the display area DPA.

The anode electrodes ANO may overlap the first emission area ELA1, the second emission area ELA2, and the third emission area ELA3, respectively, and may extend at least partially to the non-emission area NELA. The anode electrodes ANO may be connected to the drain electrode DE of the thin film transistor.

In some embodiments, the anode electrode ANO may be reflective electrodes, in which case the anode electrode ANO may be a metal layer containing a metal such as Ag, Mg, Al, Pt, Pd, Au, Ni, Nd, Ir, or Cr. In another embodiment, the anode electrode ANO may further include a metal oxide layer stacked on the metal layer. In an embodiment, the anode electrode ANO may have a multilayer structure, for example, a two-layer structure of ITO/Ag, Ag/ITO, ITO/Mg, and ITO/MgF, or a three-layer structure of ITO/Ag/ITO.

The pixel defining layer 170 may be disposed on the anode electrodes ANO. The pixel defining layer 170 may define the first emission area ELA1, the second emission area ELA2, and the third emission area ELA3 as openings exposing the anode electrodes ANO, respectively.

The pixel defining layer 170 may overlap the light blocking area BA of the color filter layer CFL to be described later in the third direction DR3. In addition, the pixel defining layer 170 may overlap a bank BK, which will be described later, in the third direction DR3.

The pixel defining layer 170 may include an organic insulating material selected from the group consisting of acrylic resin, epoxy resin, phenolic resin, polyamide resin, polyimide resin, unsaturated polyester resin, polyphenylene resin, polyphenylene sulfide resin and benzocyclobutene (BCB), but embodiments are not limited thereto.

A light emitting layer OL may be disposed on the anode electrode ANO. In some embodiments, the light emitting layer OL may have a shape of a continuous film formed over the emission areas and the non-emission area NELA. In some embodiments, the light emitting layer OL may be positioned only in the display area DPA, but embodiments are not limited thereto. For example, a portion of the light emitting layer OL may be further disposed in the non-display area NDA.

In some embodiments, the light emitting layer OL may include an organic layer containing an organic material. The organic layer may include an organic light emitting layer, and in some cases, may further include a hole injection/transport layer and/or an electron injection/transport layer, as an auxiliary layer for assisting light emission.

In some embodiments, in case that the display device 10 is a micro LED display, a nano LED display or the like, the light emitting layer OL may include an inorganic material such as an inorganic semiconductor.

A cathode electrode CE may be disposed on the light emitting layer OL. In some embodiments, the cathode electrode CE may be disposed on the light emitting layer OL to have a continuous film shape formed over the emission areas ELA1, ELA2, and ELA3 and the non-emission area NELA. In other words, the cathode electrode CE may completely cover the light emitting layer OL.

The cathode electrode CE may have a semi-transmissive or transmissive property. In case that the cathode electrode CE has a thickness of tens to hundreds of angstroms, the cathode electrode CE may have a semi-transmissive property. In some embodiments, in case that the cathode electrode CE has a semi-transmissive property, the cathode electrode CE may include Ag, Mg, Cu, Al, Pt, Pd, Au, Ni, Nd, Ir, Cr, Li, Ca, LiF/Ca, LiF/Al, Mo, Ti or a compound or mixture thereof, such as a mixture of Ag and Mg. The cathode electrode CE may include a transparent conductive oxide to have a transmissive property. In some embodiments, in case that the cathode electrode CE has the transmissive property, the cathode electrode CE may include tungsten oxide (WₓOₓ), titanium oxide (TiO₂), indium tin oxide (ITO), indium zinc oxide (IZO), zinc oxide (ZnO), indium tin zinc oxide (ITZO), magnesium oxide (MgO), or the like.

The anode electrode ANO, the light emitting layer OL, and the cathode electrode CE may form the light emitting elements ED. For example, the anode electrode ANO, the light emitting layer OL, and the cathode electrode CE overlapping the first emission area ELA1 may form a first light emitting element, the anode electrode ANO, the light emitting layer OL, and the cathode electrode CE overlapping the second emission area ELA2 may form a second light emitting element, and the anode electrode ANO, the light emitting layer OL, and the cathode electrode CE overlapping the third emission area ELA3 may form a third light emitting element. Each of the first light emitting element, the second light emitting element, and the third light emitting element may emit emission light. The emission light emitted from each light emitting element ED may have a peak wavelength of 440 nm to 480 nm. That is, the emission light LE may be blue light.

The thin film encapsulation layer TFEL may be disposed on the light emitting element layer EML. The thin film encapsulation layer TFEL may be disposed on the cathode electrode CE. The thin film encapsulation layer TFEL may serve to protect components positioned thereunder from external foreign matter such as moisture. The thin film encapsulation layer TFEL may be commonly disposed in the first emission area ELA1, the second emission area ELA2, the third emission area ELA3, and the non-emission area NELA.

The thin film encapsulation layer TFEL may include a lower inorganic layer TFE1, an organic layer TFE2, and an upper inorganic layer TFE3 sequentially stacked on each other.

The lower inorganic layer TFE1 may completely cover the cathode electrode CE in the display area DPA to cover the first light emitting element, the second light emitting element, and the third light emitting element. The organic layer TFE2 may be disposed on the lower inorganic layer TFE1 to cover the first light emitting element, the second light emitting element, and the third light emitting element. The upper inorganic layer TFE3 may be disposed on the organic layer TFE2 to completely cover the organic layer TFE2.

In some embodiments, each of the lower inorganic layer TFE1 and the upper inorganic layer TFE3 may be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, or the like, but embodiments are not limited thereto.

In some embodiments, the organic layer TFE2 may be formed of acrylic resin, methacrylic resin, polyisoprene, vinyl resin, epoxy resin, urethane resin, cellulose resin, perylene resin or the like, but embodiments are not limited thereto.

The counter substrate TSUB may be disposed above the substrate SUB where the light emitting element layer EML and the thin film encapsulation layer TFEL are disposed. The color filter layer CFL and the wavelength conversion layer WCL, which is disposed on one surface of the color filter layer CFL, may be disposed on one surface of the counter substrate TSUB. Further, the display device 10 may include a low refractive layer LR and the first capping layer CPL1 disposed between the color filter layer CFL and the wavelength conversion layer WCL, and a spacer layer SPC disposed on one surface of the wavelength conversion layer WCL.

The color filter layer CFL may be disposed on the other side of the counter substrate TSUB in the third direction DR3, that is, between the counter substrate TSUB and the substrate SUB. The color filter layer CFL may include a filtering pattern area and a light blocking pattern portion BM. The light blocking pattern portion BM may surround the filtering pattern area. The filtering pattern area of the color filter layer CFL may define a light transmission area, and the light blocking pattern portion BM may define a light blocking area BA.

As illustrated in FIG. 6, the color filter layer CFL may include a first color filter 321, a second color filter 322, and a third color filter 323. The first color filter 321 may absorb both the second light and the third light except the first light, the second color filter 322 may absorb both the first light and the third light except the second light, and the third color filter 323 may absorb both the first light and the second light except the third light. In other words, the first color filter 321 may transmit the first light, the second color filter 322 may transmit the second light, and the third color filter 323 may transmit the third light.

In some embodiments, the first color filter 321 may be a blue color filter and may include a blue colorant. In the disclosure, the colorant is a concept including both a dye and a pigment. The first color filter 321 may include a base resin and the blue colorant may be dispersed in the base resin. In some embodiments, the second color filter 322 may be a green color filter and may include a green colorant. The second color filter 322 may include a base resin and the green colorant may be dispersed in the base resin. In some embodiments, the third color filter 323 may be a red color filter and may include a red colorant. The third color filter 323 may include a base resin, and the red colorant may be dispersed in the base resin.

The first color filter 321 may include a first filtering pattern area 321a and a first blocking pattern area 321b surrounding the first filtering pattern area 321a, the second color filter 322 may include a second filtering pattern area 322a and a second blocking pattern area 322b surrounding the second filtering pattern area 322a, and the third color filter 323 may include a third filtering pattern area 323a and a third blocking pattern area 323b surrounding the third filtering pattern area 323a.

Specifically, the first filtering pattern area 321a of the first color filter 321 may overlap a first transmission area TA1, and the first blocking pattern area 321b of the first color filter 321 may surround the first filtering pattern area 321a overlapping the first transmission area TA1, however may not overlap a second transmission area TA2 and a third transmission area TA3, and may overlap the light blocking area BA. The second filtering pattern area 322a of the second color filter 322 may overlap the second transmission area TA2, and the second blocking pattern area 322b of the second color filter 322 may surround the second filtering pattern area 322a overlapping the second transmission area TA2, however may not overlap the first transmission area TA1 and the third transmission area TA3, and may overlap the light blocking area BA. The third filtering pattern area 323a of the third color filter 323 may overlap the third transmission area TA3, and the third blocking pattern area 323b of the third color filter 323 may surround the third filtering pattern area 323a overlapping the third transmission area TA3, however may not overlap the first transmission area TA1 and the second transmission area TA2, and may overlap the light blocking area BA. In other words, the filtering pattern area of a color filter member 320 may include the first filtering pattern area 321a of the first color filter 321, the second filtering pattern area 322a of the second color filter 322, and the third filtering pattern area 323a of the third color filter 323, and the light blocking pattern portion BM may have a structure in which the first blocking pattern area 321b of the first color filter 321, the second blocking pattern area 322b of the second color filter 322, and the third blocking pattern area 323b of the third color filter 323 are stacked on each other.

The first filtering pattern area 321a of the first color filter 321 may function as a blocking filter that blocks red light and green light. Specifically, the first filtering pattern area 321a may selectively transmit the first light (e.g., blue light) and block or absorb the second light (e.g., green light) and the third light (e.g., red light).

The second filtering pattern area 322a of the second color filter 322 may function as a blocking filter that blocks blue light and red light. Specifically, the second filtering pattern area 322a may selectively transmit the second light (e.g., green light) and block or absorb the first light (e.g., blue light) and the third light (e.g., red light).

The third filtering pattern area 323a of the third color filter 323 may function as a blocking filter that blocks blue light and green light. Specifically, the third filtering pattern area 323a may selectively transmit the third light (e.g., red light) and block or absorb the first light (e.g., blue light) and the second light (e.g., green light).

In some embodiments, the light blocking pattern portion BM has a structure in which the first blocking pattern area 321b, the third blocking pattern area 323b, and the second blocking pattern area 322b are sequentially stacked on each other in the third direction DR3, but the disclosure is not limited thereto. For example, the light blocking pattern portion BM may not be constituted with the color filters 321, 322, and 323 described above, but may be formed as a separate organic light blocking material through coating and exposure processes of the organic light blocking material, and the like. Hereinafter, for simplicity of description, description will be made focusing on the fact that the light blocking pattern has a structure in which the first blocking pattern area 321b, the third blocking pattern area 323b, and the second blocking pattern area 322b are sequentially stacked on each other in the third direction DR3. The light blocking pattern portion BM may absorb all of the first light, the second light, and the third light through the above-described configuration.

The low refractive layer LR may be disposed on one side of the color filter layer CFL, for example, on the other side thereof in the third direction DR3. Since the low refractive layer LR has a lower refractive index than that of a first light transmitting member TPL, a second light transmitting member WCL1, and a third light transmitting member WCL2, which will be described later, it may serve to recycle light by inducing total reflection of light traveling from the first light transmitting member TPL, the second light transmitting member WCL1, and the third light transmitting member WCL2 to the low refractive layer LR.

The low refractive layer LR may include an organic material. In some embodiments, the refractive index of the low refractive layer LR may be 1.3 or less. In case that the refractive index of the low refractive layer LR is 1.3 or less, its refractive index may be significantly different from the refractive indices of the first light transmitting member TPL, the second light transmitting member WCL1, and the third light transmitting member WCL2, so that total reflection of light may sufficiently occur.

Further, the low refractive layer LR may serve to compensate and planarize stepped portions generated by the blocking pattern areas 321b, 322b, and 323b of the color filter layer CFL. Accordingly, the first capping layer CPL1 disposed on the low refractive layer LR may be formed flat.

The first capping layer CPL1 may be disposed on one surface of the low refractive layer LR to cover the low refractive layer LR. The first capping layer CPL1 may prevent impurities such as moisture or air from the outside from permeating into the low refractive layer LR or the color filter layer CFL and damaging or contaminating the filtering pattern area and the light blocking pattern portion BM of the low refractive layer LR and the color filter member 320.

The first capping layer CPL1 may contain an inorganic material. In some embodiments, the first capping layer CPL1 may include an inorganic material such as SiO₂, SiNₓ, or SiON, and may be formed as a single layer or multilayer, but embodiments are not limited thereto.

The wavelength conversion layer WCL may be disposed on one surface of the first capping layer CPL1. The wavelength conversion layer WCL may include the bank BK, the first light transmitting member TPL, the second light transmitting member WCL1, the third light transmitting member WCL2, and a second capping layer CPL2.

With reference to FIG. 6, the banks BK may be disposed on the other side of the first capping layer CPL1 in the third direction DR3 while being spaced apart from each other in the second direction DR2 to form a space for accommodating the light transmitting members. In other words, the bank BK may serve to partition a space in which the light transmitting members are disposed. The bank BK may be directly in contact with the other side surface of the first capping layer CPL1 in the third direction DR3. The bank BK may surround the light transmitting members in plan view. The bank BK may be disposed to overlap the non-emission area NELA and the light blocking area BA. The bank BK may not overlap the emission areas ELA1, ELA2, and ELA3 and the light transmission areas TA1, TA2, and TA3.

In some embodiments, the bank BK may include an organic material having photocurability or an organic material having photocurability and including a light blocking material, but embodiments are not limited thereto.

The first light transmitting member TPL may overlap the first light transmission area TAL. The second light transmitting member WCL1 may overlap the second light transmission area TA2. The third light transmitting member WCL2 may overlap the third light transmission area TA3. The first light transmitting member TPL, the second light transmitting member WCL1, and the third light transmitting member WCL2 may be referred to as a wavelength conversion layer or a wavelength conversion material layer.

The first light transmitting member TPL may be disposed in a space partitioned by the bank BK, and may overlap the first emission area ELA1 and the first transmission area TA1 in the third direction DR3. The first light transmitting member TPL may be in direct contact with the first capping layer CPL1 and the bank BK.

The first light transmitting member TPL may be a light transmission pattern that transmits incident light. The first light transmitting member TPL may intactly transmit light of a first color emitted from the light emitting element layer EML. Specifically, as described above, the emission light provided from the first light emitting element may be blue light and may pass through the first light transmitting member TPL and the first filtering pattern area 321a of the first color filter 321 to be emitted to the outside of the display device 10. In other words, first emission light L1 passing through the first transmission area TA1 in the first emission area ELA1 and emitted to the outside may be blue light.

The first light transmitting member TPL may include a base resin 330 and a light scatterer 331.

The base resin 330 may be made of an organic material having high light transmittance. In some embodiments, the base resin 330 may include an organic material such as epoxy resin, acrylic resin, cardo resin, or imide resin, but embodiments are not limited thereto.

The light scatterer 331 may have a refractive index different from that of the base resin 330 and form an optical interface with the base resin 330. The light scatterer 331 may be a light scattering particle. The light scatterer 331 may scatter light in a random direction irrespective of the incident direction of incident light, without substantially converting the wavelength of the light passing through the first light transmission area TAL.

The light scatterer 331 may be a material that scatters at least a portion of transmitted light, and may include metal oxide particles or organic particles. In some embodiments, the light scatterer 331 may include titanium oxide (TiO₂), zirconium oxide (ZrO₂), aluminum oxide (Al₂O₃), indium oxide (In₂O₃), zinc oxide (ZnO), tin oxide (SnO₂), or the like as a metal oxide, and may include an acrylic resin, a urethane-based resin, or the like as the organic particles, but embodiments are not limited thereto.

The second light transmitting member WCL1 may be disposed in a space partitioned by the bank BK, and may overlap the second emission area ELA2 and the second transmission area TA2 in the third direction DR3. The second light transmitting member WCL1 may be in direct contact with the first capping layer CPL1 and the bank BK.

The second light transmitting member WCL1 may be a wavelength conversion pattern that converts or shifts the peak wavelength of incident light into light of another specific peak wavelength to emit the light. The second light transmitting member WCL1 may convert light of the first color emitted from the light emitting element layer EML into light of a second color and emit the light. Specifically, as described above, the emission light provided from the second light emitting element may pass through the second light transmitting member WCL1 and the second filtering pattern area 322a of the second color filter 322 as blue light, be converted into green light having a peak wavelength in a range of 510 nm to about 550 nm, and be emitted to the outside of the display device 10. In other words, second emission light L2 passing through the second transmission area TA2 in the second emission area ELA2 and emitted to the outside may be green light.

The second light transmitting member WCL1 may include the base resin 330, the light scatterer 331 dispersedly disposed in the base resin 330, and a first wavelength shifter 332 dispersedly disposed in the base resin 330.

The first wavelength shifter 332 may convert or shift the peak wavelength of incident light to another specific peak wavelength. The first wavelength shifter 332 may convert the emission light, which is the blue light provided by the second light emitting element, into green light having a single peak wavelength in a range of about 510 nm to about 550 nm and emit the green light.

In some embodiments, the first wavelength shifter 332 may be a quantum dot, a quantum rod, or a fluorescent substance, but embodiments are not limited thereto. Hereinafter, for simplicity of description, the first wavelength shifter 332 will be mainly described as a quantum dot. The quantum dot may be a particulate material that emits light of a specific color in case that an electron transitions from a conduction band to a valence band. The quantum dot may be a semiconductor nanocrystal material. The quantum dot may have a specific band gap according to its composition and size. Thus, the quantum dot may absorb light and emit light having an intrinsic wavelength. Examples of semiconductor nanocrystal of quantum dots may include group IV nanocrystal, group II-VI compound nanocrystal, group III-V compound nanocrystal, group IV-VI nanocrystal, a combination thereof, or the like.

The group II-VI compound may be selected from the group consisting of binary compounds, ternary compounds, and quaternary compounds, wherein the binary compounds are selected from the group consisting of CdSe, CdTe, ZnS, ZnSe, ZnTe, ZnO, HgS, HgSe, HgTe, MgSe, MgS and mixtures thereof, the ternary compounds are selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof, and the quaternary compounds are selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

The group III-V compound may be selected from the group consisting of binary compounds, ternary compounds, and quaternary compounds, wherein the binary compounds are selected from the group consisting of GaN, GaP, GaAs, GaSb, AlN, AlP, AlAs, AlSb, InN, InP, InAs, InSb and mixtures thereof, the ternary compounds are selected from the group consisting of GaNP, GaNAs, GaNSb, GaPAs, GaPSb, AlNP, AlNAs, AlNSb, AlPAs, AlPSb, InGaP, InNP, InAIP, InNAs, InNSb, InPAs, InPSb, GaAlNP and mixtures thereof, and the quaternary compounds are selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof.

The group IV-VI compound may be selected from the group consisting of binary compounds, ternary compounds, and quaternary compounds, wherein the binary compounds are selected from the group consisting of SnS, SnSe, SnTe, PbS, PbSe, PbTe and mixtures thereof, the ternary compounds are selected from the group consisting of SnSeS, SnSeTe, SnSTe, PbSeS, PbSeTe, PbSTe, SnPbS, SnPbSe, SnPbTe and mixtures thereof, and the quaternary compounds are selected from the group consisting of SnPbSSe, SnPbSeTe, SnPbSTe and mixtures thereof. The group IV element may be selected from the group consisting of Si, Ge and mixtures thereof. The group IV compound may be a binary compound selected from the group consisting of SiC, SiGe and mixtures thereof.

In this case, the binary compound, the tertiary compound or the quaternary compound may exist in particles at a uniform concentration, or may exist in the same particle divided into states where concentration distributions are partially different. Further, the particles may have a core/shell structure in which one quantum dot surrounds another quantum dot. An interface between the core and the shell may have a concentration gradient in which the concentration of elements present in the shell decreases toward the center.

In some embodiments, the quantum dot may have a core-shell structure including a core including the nanocrystal described above and a shell surrounding the core. The shell of the quantum dot may serve as a protective layer for maintaining semiconductor characteristics by preventing chemical denaturation of the core and/or as a charging layer for giving electrophoretic characteristics to the quantum dot. The shell may be a single layer or a multilayer. An interface between the core and the shell may have a concentration gradient in which the concentration of elements present in the shell decreases toward the center. Examples of the shell of the quantum dot may include a metal or non-metal oxide, a semiconductor compound, and a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, or a tertiary compound such as MgAl₂O₄, CoFe₂O₄, NiFe₂O₄ and CoMn₂O₄, but the disclosure is not limited thereto.

In addition, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb or the like, but the disclosure is not limited thereto.

The light emitted from the first wavelength shifter 332 may have a full width of half maximum (FWHM) of the emission wavelength spectrum, which is about 45 nm or less, about 40 nm or less, or about 30 nm or less. Thus, the purity and reproducibility of colors displayed by the display device 10 can be further improved. In addition, the light emitted from the first wavelength shifter 332 may be emitted in various directions regardless of the incident direction of incident light. Accordingly, side visibility of the second color displayed in the second transmission area TA2 may be improved.

Some of the emission light provided from the second light emitting element may pass through the second light transmitting member WCL1 and be emitted without being converted into green light by the first wavelength shifter 332. Among the emission light, a component whose wavelength is not converted by the second light transmitting member WCL1 and which is incident on the second filtering pattern area 322a of the second color filter 322 may be blocked by the second filtering pattern area 322a. On the other hand, among the emission light, green light converted by the second light transmitting member WCL1 passes through the second filtering pattern area 322a and is emitted to the outside. That is, the second emission light L2 emitted to the outside of the display device 10 through the second transmission area TA2 may be green light.

The third light transmitting member WCL2 may be disposed in a space partitioned by the bank BK, and may overlap the third emission area ELA3 and the third transmission area TA3 in the third direction DR3. The third light transmitting member WCL2 may be in direct contact with the first capping layer CPL1 and the bank BK.

The third light transmitting member WCL2 may be a wavelength conversion pattern that converts or shifts the peak wavelength of incident light into light of another specific peak wavelength to emit the light. Specifically, as described above, the emission light provided from the second light emitting element may pass through the second light transmitting member WCL1 and the second filtering pattern area 322a of the second color filter 322 as blue light, be converted into red light having a peak wavelength in a range of about 610 nm to about 650 nm, and be emitted to the outside of the display device 10. In other words, the third emission light L3 that passes through the third transmission area TA3 in the third emission area ELA3 and emitted to the outside may be red light.

The third light transmitting member WCL2 may include the base resin 330, the light scatterer 331 dispersedly disposed in the base resin 330, and a second wavelength shifter 333 dispersedly disposed in the base resin 330.

The second wavelength shifter 333 may convert or shift the peak wavelength of incident light to another specific peak wavelength. The second wavelength shifter 333 may convert the emission light, which is the blue light provided by the third light emitting element, into red light having a single peak wavelength in a range of about 610 nm to about 650 nm and emit the red light. In some embodiments, the second wavelength shifter 333 may be a quantum dot, a quantum rod, or a fluorescent substance, but embodiments are not limited thereto. The case where the second wavelength shifter 333 is a quantum dot has substantially the same configuration as the case where the first wavelength shifter 332 is a quantum dot as described above, and thus a description thereof will be omitted.

Some of the emission light provided from the third light emitting element may pass through the second light transmitting member WCL1 and be emitted without being converted into red light by the second wavelength shifter 333. Among the emission light, a component whose wavelength is not converted by the third light transmitting member WCL2 and is incident on the third filtering pattern area 323a of the third color filter 323 may be blocked by the third filtering pattern area 323a. On the other hand, the red light converted by the third light transmitting member WCL2 among the emission light passes through the third filtering pattern area 323a and is emitted to the outside. That is, the third emission light L3 emitted to the outside of the display device 10 through the third transmission area TA3 may be red light.

The second capping layer CPL2 may be disposed on the bank BK, the first light transmitting member TPL, the second light transmitting member WCL1, and the third light transmitting member WCL2, and serve to prevent impurities such as moisture or air from permeating from the outside and damaging or contaminating the first light transmitting member TPL, the second light transmitting member WCL1, and the third light transmitting member WCL2. The second capping layer CPL2 may cover the first light transmitting member TPL, the second light transmitting member WCL1, and the third light transmitting member WCL2.

The spacer layer SPC may be disposed on one surface of the second capping layer CPL2. The spacer layer SPC may maintain a cell gap between the substrate SUB and the counter substrate TSUB. The spacer layer SPC may surround the light transmitting members in plan view. The spacer layer SPC may be disposed to overlap the non-emission area NELA and the light blocking area BA. The spacer layer SPC may not overlap the emission areas ELA1, ELA2, and ELA3 and the light transmission areas TA1, TA2, and TA3.

In some embodiments, the spacer layer SPC may include a transparent organic material having photocurability or an organic material having photocurability and containing a light blocking material, but embodiments are not limited thereto. In some embodiments, the spacer layer SPC may be formed of acrylic resin, methacrylic resin, polyisoprene, vinyl resin, epoxy resin, urethane resin, cellulose resin, perylene resin or the like, but embodiments are not limited thereto.

The filling layer FIL may be disposed between the counter substrate TSUB and the substrate SUB. The filling layer FIL may be between the wavelength conversion layer WCL and the thin film encapsulation layer TFEL to fill the space between the wavelength conversion layer WCL and the thin film encapsulation layer TFEL. Specifically, in some embodiments, the filling layer FIL may be in direct contact with the upper inorganic layer TFE3 of the thin film encapsulation layer TFEL and the second capping layer CPL2 of the wavelength conversion layer WCL, but the disclosure is not limited thereto.

In some embodiments, the filling layer FIL may be made of a material having an extinction coefficient of substantially zero. There is a correlation between a refractive index and an extinction coefficient, and as the refractive index decreases, the extinction coefficient also decreases. In addition, in case that the refractive index is 1.7 or less, the extinction coefficient may substantially converge to zero. In some embodiments, the filling layer FIL may be made of a material having a refractive index of 1.7 or less, so that it is possible to prevent or minimize light provided from the self-light emitting element from being absorbed while passing through the filling layer FIL. In some embodiments, the filling layer FIL may be made of an organic material having a refractive index of 1.4 to 1.6.

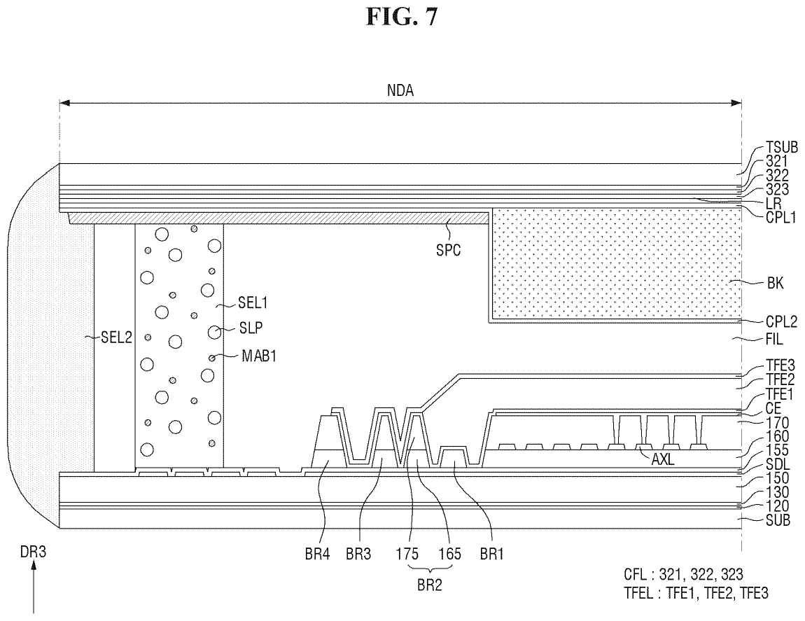

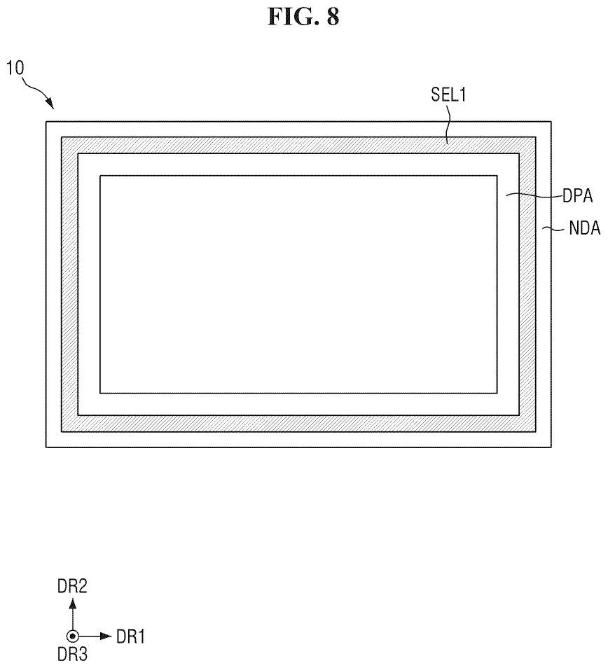

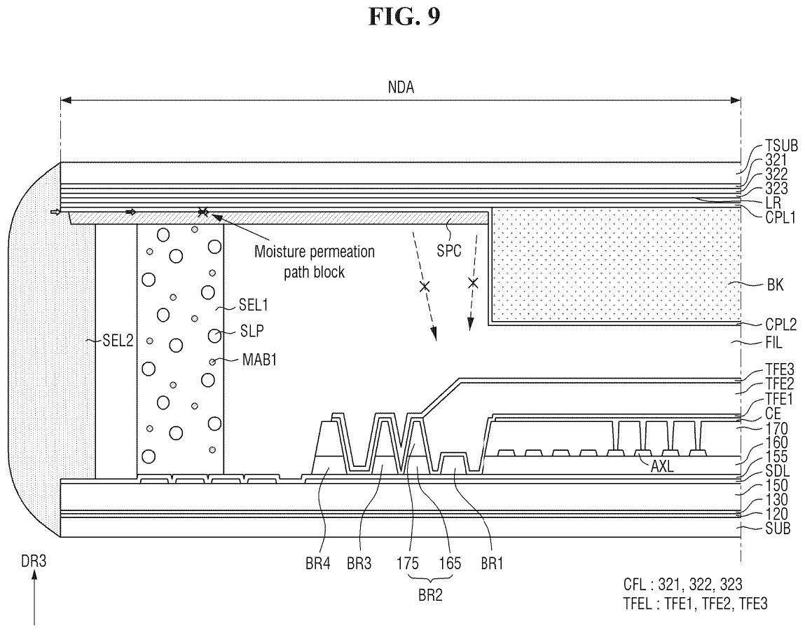

FIG. 7 is a schematic cross-sectional view illustrating a non-display area of a display device according to an embodiment. FIG. 8 is a schematic plan view showing arrangement of a first coupling member of a display device according to an embodiment. FIG. 9 is a schematic cross-sectional view showing a moisture permeation path in a display device.

Referring to FIGS. 7 and 8 in conjunction with FIG. 6, in addition to multiple layers extending from the display area DPA, partition walls BR1, BR2, BR3, and BR4, the first coupling member SEL1, and the second coupling member SEL2 may be disposed in the non-display area NDA of the display device 10.

Specifically, the buffer layer 120, the first insulating layer 130, the second insulating layer 150, and the third insulating layer 155 extending from the display area DPA may be disposed on the substrate SUB in the non-display area NDA. The buffer layer 120, the first insulating layer 130, the second insulating layer 150, and the third insulating layer 155 may be disposed to extend to the lateral side of the substrate SUB, and the lateral sides thereof may be aligned with the lateral side of the substrate SUB.

A connection line SDL may be disposed between the second insulating layer 150 and the third insulating layer 155. The connection line SDL may be a signal line connected to a thin film transistor in the display area DPA. In some embodiments, the connection line SDL may be a gate line or a sensing line. In some embodiments, the connection line SDL may be a routing line connected to a thin film transistor in the display area DPA.

The fourth insulating layer 160 may be disposed on the third insulating layer 155. The fourth insulating layer 160 may extend from the display area DPA to the non-display area NDA.

An auxiliary electrode AXL may be disposed on the fourth insulating layer 160. The auxiliary electrode AXL may be electrically connected to the cathode electrode CE extending from the display area DPA. The auxiliary electrode AXL may have the same structure as the aforementioned anode electrode ANO. In some embodiments, the auxiliary electrode AXL may be a second voltage line that applies a second voltage to the cathode electrode CE. In some embodiments, the auxiliary electrode AXL may be a routing line that electrically connects the second power pad to the cathode electrode CE.

The pixel defining layer 170 covering the auxiliary electrode AXL may be disposed on the fourth insulating layer 160. The pixel defining layer 170 may extend from the display area DPA to the non-display area NDA. The pixel defining layer 170 may include contact holes exposing the auxiliary electrode AXL disposed thereunder.

The cathode electrode CE may be disposed on the pixel defining layer 170. The cathode electrode CE may extend from the display area DPA to the non-display area NDA. The cathode electrode CE may be electrically connected to the auxiliary electrode AXL through the contact holes disposed in the pixel defining layer 170. The contact holes may be provided in plural numbers to reduce the contact resistance between the cathode electrode CE and the auxiliary electrode AXL.

The partition walls BR1, BR2, BR3, and BR4 may be disposed on the third insulating layer 155. The partition walls BR1, BR2, BR3, and BR4 may prevent an overflow of the organic layer TFE2 of the thin film encapsulation layer TFEL extending from the display area DPA.

The partition walls BR1, BR2, BR3, and BR4 may include a first partition wall BR1, a second partition wall BR2, a third partition wall BR3, and a fourth partition wall BR4 that are arranged sequentially from the display area DPA to the non-display area NDA. The partition walls BR1, BR2, BR3, and BR4 may be arranged to be spaced apart from each other.

The first partition wall BR1 may have a single layer structure. The first partition wall BR1 may include the same material as the fourth insulating layer 160. The first partition wall BR1 may be formed through the same mask process as the fourth insulating layer 160.

Each of the second partition wall BR2, the third partition wall BR3, and the fourth partition wall BR4 may have a multilayer structure. Each of the second partition wall BR2, the third partition wall BR3, and the fourth partition wall BR4 may include a first layer 165 and a second layer 175 stacked on the first layer 165. The first layer 165 may be disposed directly on the third insulating layer 155 and may include the same material as the fourth insulating layer 160. The first layer 165 may be formed through the same mask process as the fourth insulating layer 160. The second layer 175 may be disposed directly on the first layer 165 and may include the same material as the pixel defining layer 170. The second layer 175 may be formed through the same mask process as the pixel defining layer 170.

The thin film encapsulation layer TFEL may extend from the display area DPA to be disposed in the non-display area NDA. The lower inorganic layer TFE1 and the upper inorganic layer TFE3 of the thin film encapsulation layer TFEL may be disposed to cover the first partition wall BR1, the second partition wall BR2, the third partition wall BR3, and the fourth partition wall BR4. In some embodiments, the lower inorganic layer TFE1 and the upper inorganic layer TFE3 may completely cover the first partition wall BR1, the second partition wall BR2, and the third partition wall BR3, and partially cover the fourth partition wall BR4. In some embodiments, the lower inorganic layer TFE1 and the upper inorganic layer TFE3 may completely cover the first partition wall BR1, the second partition wall BR2, the third partition wall BR3, and the fourth partition wall BR4.

The organic layer TFE2 may be disposed between the lower inorganic layer TFE1 and the upper inorganic layer TFE3 to cover the first partition wall BR1 and the second partition wall BR2. In some embodiments, the organic layer TFE2 may completely cover the first partition wall BR1 and partially cover the second partition wall BR2.

The color filter layer CFL, the low refractive layer LR, and the first capping layer CPL1 may extend from the display area DPA to be disposed on one surface of the counter substrate TSUB in the non-display area NDA. For example, the first color filter 321, the second color filter 322, the third color filter 323, the low refractive layer LR, and the first capping layer CPL1 may be sequentially stacked on each other. The first color filter 321, the second color filter 322, the third color filter 323, the low refractive layer LR, and the first capping layer CPL1 may extend to the non-display area NDA and may be aligned and coincide with the lateral side of the counter substrate TSUB. However, the disclosure is not limited thereto, and the first color filter 321, the second color filter 322, the third color filter 323, the low refractive layer LR, and the first capping layer CPL1 may be disposed to be spaced apart from the lateral side of the counter substrate TSUB.

The bank BK and the second capping layer CPL2 may be disposed on the first capping layer CPL1. The bank BK and the second capping layer CPL2 may be disposed to extend from the display area DPA to the non-display area NDA. The second capping layer CPL2 may be disposed to cover the bank BK and the first capping layer CPL1.

The spacer layer SPC may be disposed on the second capping layer CPL2. The spacer layer SPC may be disposed to extend from the display area DPA to the non-display area NDA. In some embodiments, the spacer layer SPC may be disposed in a shape of patterns separated from the display area DPA.

The filling layer FIL may extend from the display area DPA to be disposed between the substrate SUB and the counter substrate TSUB in the non-display area NDA. The filling layer FIL may be in contact with the upper inorganic layer TFE3 and the third insulating layer 155, and may be in contact with the spacer layer SPC and the second capping layer CPL2. In addition, the filling layer FIL may be in contact with the first coupling member SEL1 to be accommodated in a space partitioned by the substrate SUB, the counter substrate TSUB, and the first coupling member SELL.

The first coupling member SEL1 and the second coupling member SEL2 may be disposed in the non-display area NDA of the display device 10. The first coupling member SEL1 and the second coupling member SEL2 may couple the substrate SUB to the counter substrate TSUB and may prevent moisture permeation from the outside.

The first coupling member SEL1 may be disposed adjacent to the display area DPA to surround the display area DPA in plan view. The first coupling member SEL1 may be disposed in a closed loop shape to surround the display area DPA in plan view. One surface of the first coupling member SEL1 may be positioned on the third insulating layer 155, and the other surface of the first coupling member SEL1 may be positioned on the spacer layer SPC. For example, the bottom surface of the first coupling member SEL1 may be in direct contact with the third insulating layer 155, and the top surface of the first coupling member SEL1 may be in direct contact with the spacer layer SPC.

As described above, the spacer layer SPC may be provided to maintain the cell gap between the substrate SUB and the counter substrate TSUB, and may include an organic material. Due to the characteristics of an organic material, it may be difficult to prevent moisture permeation. The spacer layer SPC formed of an organic material or the interface between the spacer layer SPC and the second capping layer CPL2 may act as a path through which external moisture permeates to the inside. Moisture permeating through this path may oxidize the upper inorganic layer TFE3 of the thin film encapsulation layer TFEL, and permeate into the organic layer TFE2 to cause delamination at the interface between the lower inorganic layer TFE1 and the organic layer TFE2. Accordingly, dark spots may occur in the display device 10, resulting in display defects.

In an embodiment, in order to block or absorb moisture permeating into the spacer layer SPC or the interface between the spacer layer SPC and the second capping layer CPL2, the first coupling member SEL1 may include a first moisture absorbent MAB1.

The first coupling member SEL1 may include an ultraviolet ray (UV) curable resin. In some embodiments, the UV curable resin may be an acrylate-based resin. The first coupling member SEL1 may include the first moisture absorbent MAB1. The first moisture absorbent MAB1 may adsorb or remove moisture or oxygen permeating from the outside through a physical or chemical reaction.

The first moisture absorbent MAB1 may include at least one of metal salt and metal oxide. In some embodiments, the metal oxide may be lithium oxide (Li₂O), sodium oxide (Na₂O), barium oxide (BaO), calcium oxide (CaO), magnesium oxide (MgO), or the like. The metal salt may be sulfate such as lithium sulfate (Li₂SO₄), sodium sulfate (Na₂SO₄), calcium sulfate (CaSO₄), magnesium sulfate (MgSO₄), cobalt sulfate (CoSO₄), gallium sulfate (Ga₂(SO₄)₃), titanium sulfate (Ti(SO₄)₂) or nickel sulfate (NiSO₄), metal halides such as calcium chloride (CaCl₂), magnesium chloride (MgCl₂), strontium chloride (SrCl₂), yttrium chloride (YCl₃), copper chloride (CuCl₂), cesium fluoride (CsF), tantalum fluoride (TaF₅), niobium fluoride (NbF₅), lithium bromide (LiBr), calcium bromide (CaBr₂), cesium bromide (CeBr₃), selenium bromide (SeBr₄), vanadium bromide (VBr₃), magnesium bromide (MgBr₂), barium iodide (BaI₂) or magnesium iodide (MgI₂), barium perchlorate (Ba(ClO₄)₂), magnesium perchlorate (Mg(ClO₄)₂), or the like. However, the disclosure is not limited thereto.

The particle size of the first moisture absorbent MAB1 may range from 10 nm to 1000 nm. In some embodiments, the first moisture absorbent MAB1 may be made of the same material or made of different materials. In some embodiments, the first moisture absorbent MAB1 may be made of particles having the same size or different sizes.

The first moisture absorbent MAB1 may be included in an amount of 20% to 50% by weight with respect to the total weight of the first coupling member SELL. In case that the content of the first moisture absorbent MAB1 is in the above range, moisture absorptivity may be given to the first coupling member SEL1 while maintaining the processability of the first coupling member SELL.

The first coupling member SEL1 may further include spacer particles SLP. The spacer particles SLP may serve to strengthen the supporting force of the first coupling member SELL. In some embodiments, the spacer particles SLP may be ball spacers. Further, in some embodiments, the spacer particles SLP may be made of particles containing organic or inorganic materials.

Referring to FIG. 9, external moisture and oxygen may permeate to the inside along the spacer layer SPC made of an organic material or the interface between the spacer layer SPC and the second capping layer CPL2. The first coupling member SEL1 containing the first moisture absorbent MAB1 of the disclosure is in direct contact with the spacer layer SPC, so that moisture and oxygen moving along the spacer layer SPC may be absorbed or removed by the first moisture absorbent MAB1 of the spacer layer SPC. Accordingly, the moisture permeation path in the area in contact with the first coupling member SEL1 may be blocked, thereby preventing oxidation of the upper inorganic layer TFE3 and delamination of the organic layer TFE2 and the lower inorganic layer TFE1 in the display device 10.

The second coupling member SEL2 may encapsulate the side surfaces of the substrate SUB and the counter substrate TSUB that are coupled by the first coupling member SELL. The second coupling member SEL2 may directly cover the side surfaces of the substrate SUB and the counter substrate TSUB. In some embodiments, the second coupling member SEL2 may be disposed partially inwardly between the substrate SUB and the counter substrate TSUB. For example, the second coupling member SEL2 may cover a portion of the spacer layer SPC and a portion of the third insulating layer 155.

The second coupling member SEL2 may be in contact with the side surface of at least one of the counter substrate TSUB, the color filter layer CFL, the low refractive layer LR, the first capping layer CPL1, the second capping layer CPL2, and the spacer layer SPC. In some embodiments, the second coupling member SEL2 may be in contact with the respective side surfaces of the counter substrate TSUB, the color filter layer CFL, the low refractive layer LR, the first capping layer CPL1, the second capping layer CPL2, and the spacer layer SPC.

The second coupling member SEL2 may be disposed to be spaced apart from the first coupling member SELL. However, the disclosure is not limited thereto, and the second coupling member SEL2 and the first coupling member SEL1 may be partially in contact with each other. Pores may be disposed in a space between the first coupling member SEL1 and the second coupling member SEL2.

As described above, the display device 10 according to an embodiment may include the first moisture absorbent MAB1 in the first coupling member SEL1 that is in contact with the spacer layer SPC, so that a moisture permeation path caused by the spacer layer SPC may be blocked or removed to prevent defects in the display device 10.

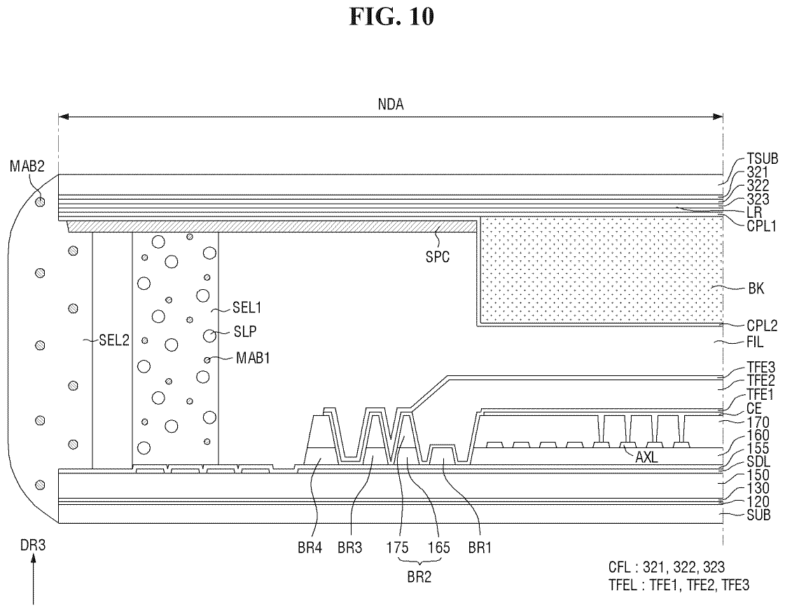

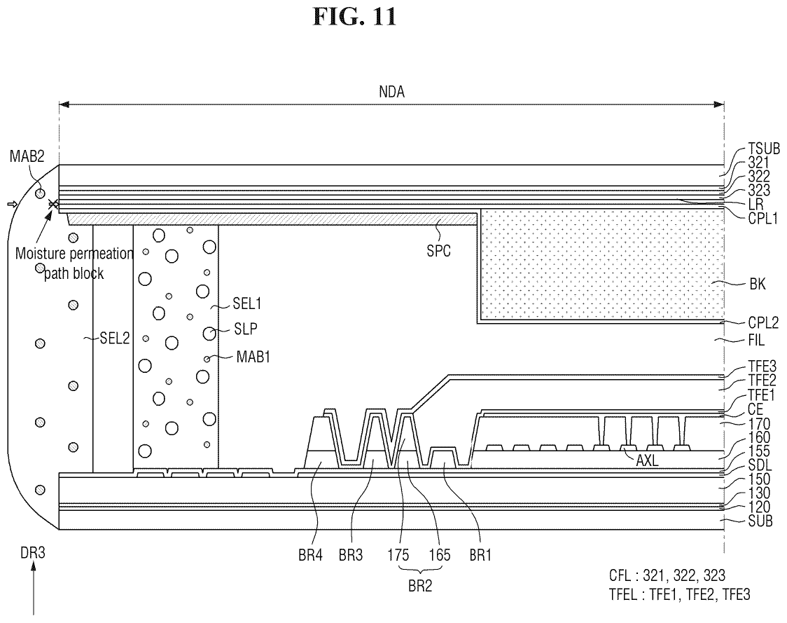

FIG. 10 is a schematic cross-sectional view of a display device according to another embodiment. FIG. 11 is a schematic cross-sectional view showing a moisture permeation path of a display device.

Referring to FIGS. 10 and 11, this embodiment may be different from the embodiment of FIGS. 7 to 9 at least in that the second coupling member SEL2 further includes a second moisture absorbent MAB2. Hereinafter, the redundant description will be omitted and differences will be described.

The display device 10 according to an embodiment may include moisture absorbents in the first coupling member SEL1 and the second coupling member SEL2, respectively. Specifically, the first coupling member SEL1 may include the first moisture absorbent MAB1, and the second coupling member SEL2 may include the second moisture absorbent MAB2.

The second coupling member SEL2 may include a UV curable resin. In some embodiments, the UV curable resin may be an acrylate-based resin. The second coupling member SEL2 may include the second moisture absorbent MAB2. The second moisture absorbent MAB2 may adsorb or remove moisture or oxygen permeating from the outside through a physical or chemical reaction. The second moisture absorbent MAB2 may include the materials discussed above as the first moisture absorbent MAB1.

The particle size of the second moisture absorbent MAB2 may range from 10 nm to 1000 nm. In some embodiments, the second moisture absorbent MAB2 may be made of the same material or made of different materials. In some embodiments, the second moisture absorbent MAB2 may be made of particles having the same size or different sizes.

The second moisture absorbent MAB2 may be included in an amount of 20% to 50% by weight with respect to the total weight of the second coupling member SEL2. In case that the content of the second moisture absorbent MAB2 is in the above range, moisture absorptivity may be given to the second coupling member SEL2 while maintaining the processability of the second coupling member SEL2.

The aforementioned low refractive layer LR may include an organic material. Due to the characteristics of an organic material, it may be difficult to prevent moisture permeation. The low refractive layer LR made of an organic material or the interface between the low refractive layer LR and the first capping layer CPL1 may act as a path through which external moisture permeates to the inside. Moisture permeating through this path may cause delamination at the interface between the first color filter 321 of the color filter layer CFL and the counter substrate TSUB. Accordingly, the color filter layer CFL lifting of the display device 10 may occur, resulting in display defects.

In an embodiment, by disposing the second coupling member SEL2 including the second moisture absorbent MAB2, it is possible to block or absorb moisture permeating from the side surface of the display device 10 into the low refractive layer LR or the interface between the low refractive layer LR and the first capping layer CPL1. Accordingly, the moisture permeation path caused by the low refractive layer LR is blocked, thereby preventing delamination at the interface between the first color filter 321 and the counter substrate TSUB of the display device 10.

In an embodiment, it has been described as an example that the first coupling member SEL1 includes the first moisture absorbent MAB1 and the second coupling member SEL2 includes the second moisture absorbent MAB2, but the disclosure is not limited thereto. For example, an embodiment, in which the second coupling member SEL2 includes the second moisture absorbent MAB2 without including the first moisture absorbent MAB1 in the first coupling member SEL1, is also applicable.

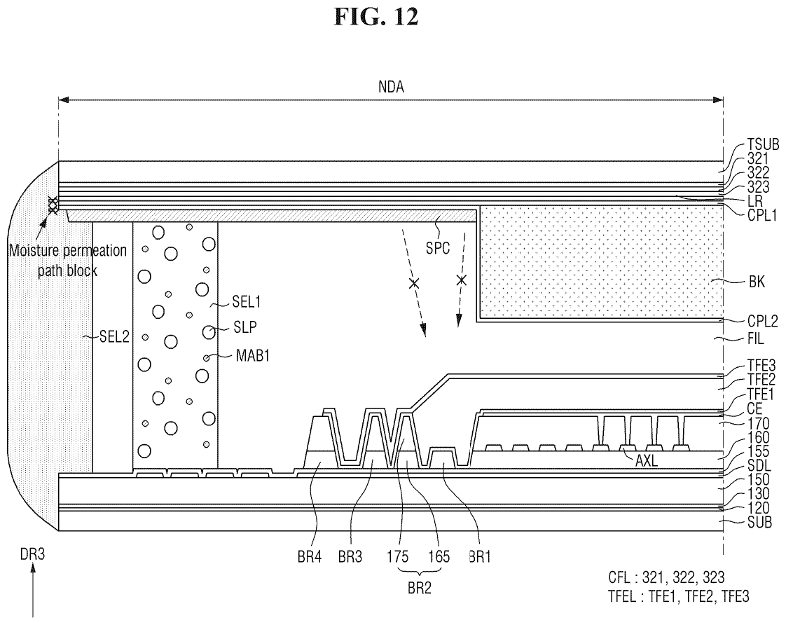

FIG. 12 is a schematic cross-sectional view showing a display device according to still another embodiment.

Referring to FIG. 12, this embodiment may be different from the embodiment of FIGS. 7 to 9 at least in the formation of the first capping layer CPL1 and/or the second capping layer CPL2.

The first capping layer CPL1 may cover and protect the low refractive layer LR. The first capping layer CPL1 may be disposed in direct contact with one surface of the low refractive layer LR. The first capping layer CPL1 may be made of an inorganic material to protect the low refractive layer LR, but it may be difficult to block moisture permeation 100%. Further, the second capping layer CPL2 may cover and protect the bank BK, the first light transmitting member TPL, the second light transmitting member WCL1, and the third light transmitting member WCL2. The second capping layer CPL2 may also be made of an inorganic material, but it may be difficult to block moisture permeation 100%. Therefore, in an embodiment, the first capping layer CPL1, the second capping layer CPL2, or the first capping layer CPL1 and the second capping layer CPL2 may be formed of silicon oxynitride (SiₓO_{y}N_{z}) in order to improve barrier characteristics of the first capping layer CPL1, the second capping layer CPL2, or the first capping layer CPL1 and the second capping layer CPL2. In some embodiments, the first capping layer CPL1 may include silicon oxynitride (SiₓO_{y}N_{z}). In some embodiments, the second capping layer CPL2 may include silicon oxynitride (SiₓO_{y}N_{z}). In some embodiments, the first capping layer CPL1 and the second capping layer CPL2 may include silicon oxynitride (SiₓO_{y}N_{z}).

For example, the first capping layer CPL1 or the second capping layer CPL2 may include silicon oxynitride (SiₓO_{y}N_{z}) represented by Chemical Formula 1:

SiₓO_{y}N_{z} (30≤x≤40, 1≤y≤5, and 55≤z≤70), [Chemical Formula 1]
where the unit is atomic %.

As shown in Chemical Formula 1, silicon oxynitride (SiₓO_{y}N_{z}) may be formed so that the atomic ratio of oxygen is relatively small and the atomic ratio of nitrogen is relatively large. As the atomic ratio of oxygen in silicon oxynitride (SiₓO_{y}N_{z}) decreases, oxidation occurs more actively, and thus it may be oxidized in contact with moisture permeating from the outside. That is, silicon oxynitride (SiₓO_{y}N_{z}) may capture moisture permeating from the outside to block moisture permeation. In addition, if the atomic ratio of nitrogen increases, the refractive index of the layer may increase. An increase in the refractive index of the first capping layer CPL1 may decrease light transmitted through the low refractive layer LR, thereby deteriorating luminous efficiency.

In addition, silicon oxynitride (SiₓO_{y}N_{z}) according to Chemical Formula 1 may decrease damage caused by plasma during the film fabrication process, and reduce outgassing of H₂O. In some embodiments, in silicon oxynitride (SiₓO_{y}N_{z}) of the first capping layer CPL1 or the second capping layer CPL2, the atomic ratio of nitrogen may be greater than the atomic ratio of silicon and the atomic ratio of oxygen, and the atomic ratio of silicon may be greater than the atomic ratio of oxygen.

Therefore, in an embodiment, the first capping layer CPL1 or the second capping layer CPL2 may be formed of silicon oxynitride (SiₓO_{y}N_{z}) having an atomic ratio of silicon of 30% to 40%, an atomic ratio of oxygen of 1% to 5%, and an atomic ratio of nitrogen of 55% to 70%, thereby blocking moisture permeation to improve barrier characteristics and preventing a decrease in luminous efficiency.

Hereinafter, an experimental example of the aforementioned display device 10 will be described.

### Fabrication Example: Fabrication of Display Device

### Example

A display device including the spacer layer SPC and the first coupling member SEL1 shown in FIG. 7 was fabricated. Here, the first coupling member SEL1 contained 30% by weight of a CaO moisture absorbent.

### Comparative Examples 1 and 2

Display devices were fabricated under the same conditions as the example without including a moisture absorbent in the first coupling member SELL.

### Experimental Example 1: OH Measurement of Spacer Layer and First Coupling Member

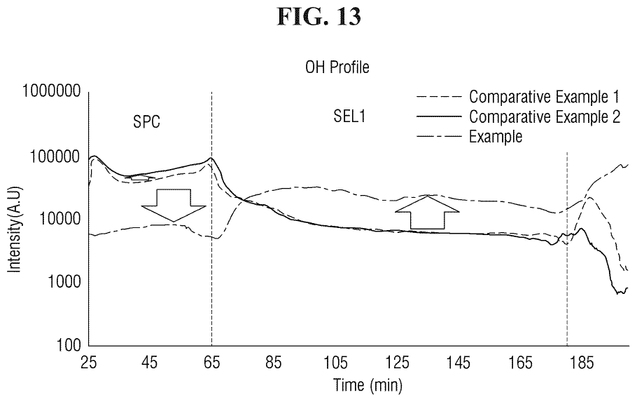

After subjecting the display devices fabricated according to Example and Comparative Examples 1 and 2 to reliability test conditions (high temperature and high humidity), OH contents of the spacer layer and the first coupling member over time were measured using a dynamic secondary ion mass spectrometer (D-SIMS). The results are shown in FIG. 13.

FIG. 13 is a schematic graph showing the OH contents of the spacer layer and the first coupling member according to Experimental Example 1. In FIG. 13, the horizontal axis indicates time and the vertical axis indicates intensity of OH.

Referring to FIG. 13, compared to Comparative Examples 1 and 2, the OH content of the spacer layer SPC was decreased and the OH content of the first coupling member SEL1 was increased in Example.

Through these results, it was confirmed that the display device of Example includes the moisture absorbent in the first coupling member SEL1, and thus the moisture that permeates into the spacer layer SPC is absorbed by the moisture absorbent of the first coupling member SELL.

### Experimental Example 2: Moisture Permeability Evaluation

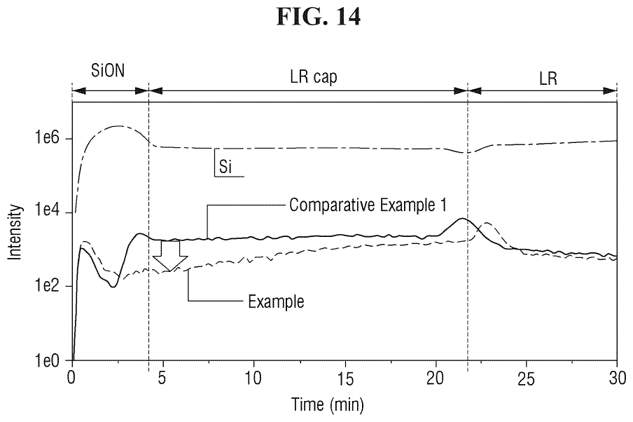

Display devices fabricated according to Comparative Example 1 and Example were prepared. Here, the first capping layer of Comparative Example 1 was made of SiON (the atomic ratio of 0 was 55% and the atomic ratio of N was 5%), and the first capping layer of Example was made of SiON (the atomic ratio of 0 was 5% and the atomic ratio of N was 55%). After subjecting the display devices to reliability test conditions (high temperature and high humidity), a D content of D₂O (heavy water) in the first capping layer (LR cap) over time was measured using the D-SIMS. Since H of H₂O cannot be analyzed, D represents H by replacing H with D. These results are shown in FIG. 14.

FIG. 14 is a schematic graph showing the D contents of D₂O in the low refractive layer and the first capping layer according to Experimental Example 2.

Referring to FIG. 14, the D content of the first capping layer in Example was significantly decreased compared to that of the first capping layer in Comparative Example 1.

Through these results, it was confirmed that the first capping layer of Example can reduce moisture permeation by containing different atomic ratios of SiON.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device, comprising:
a substrate comprising a display area and a non-display area;
a light emitting element layer disposed on the display area of the substrate;
a counter substrate facing the substrate;
a low refractive layer disposed on a surface of the counter substrate;
a first capping layer disposed on a surface of the low refractive layer;
a second capping layer disposed on a surface of the first capping layer;
a spacer layer disposed on a surface of the second capping layer;
a first coupling member between the substrate and the counter substrate, and coupling the substrate to the counter substrate; and
a second coupling member disposed on side surfaces of the substrate and the counter substrate, and coupling the substrate to the counter substrate, wherein
the first coupling member extends to the spacer layer, and
the first coupling member contains a first moisture absorbent.

2. The display device of claim 1, wherein the first coupling member surrounds the display area in plan view.

3. The display device of claim 1, wherein the first moisture absorbent is contained in an amount of 20% to 50% by weight with respect to a total weight of the first coupling member.

4. The display device of claim 1, wherein the first coupling member further contains spacer particles.

5. The display device of claim 1, wherein
the second coupling member is spaced apart from the first coupling member, and
the second coupling member surrounds the first coupling member in plan view.

6. The display device of claim 1, wherein the second coupling member contains a second moisture absorbent.

7. The display device of claim 6, wherein the second moisture absorbent is contained in an amount of 20% to 50% by weight with respect to a total weight of the second coupling member.

8. The display device of claim 1, wherein the second coupling member extends to a side surface of each of the low refractive layer, the first capping layer, the second capping layer, and the spacer layer.

9. The display device of claim 1, wherein at least one of the first capping layer and the second capping layer contains silicon oxynitride represented by Chemical Formula 1:
SiₓO_{y}N_{z} (30≤x≤40, 1≤y≤5, and 55≤z≤70), [Chemical Formula 1]
where the unit is atomic %.

10. The display device of claim 1, further comprising:
a color filter layer between the counter substrate and the low refractive layer, wherein
the color filter layer comprises a first color filter disposed on a surface of the counter substrate, a second color filter disposed on a surface of the first color filter, and a third color filter disposed on a surface of the second color filter, and
the second coupling member extends to a side surface of the color filter layer.

11. The display device of claim 1, further comprising:
a wavelength conversion layer between the first capping layer and the second capping layer,
wherein the wavelength conversion layer comprises:
a first light transmitting member which intactly transmits first color light emitted from the light emitting element layer,
a second light transmitting member which converts the first color light emitted from the light emitting element layer into second color light, and
a third light transmitting member which converts the first color light emitted from the light emitting element layer into third color light.

12. The display device of claim 1, further comprising:
a thin film encapsulation layer disposed on the light emitting element layer,
wherein the thin film encapsulation layer comprises:
a lower inorganic layer overlapping the light emitting element layer,
an organic layer disposed on the lower inorganic layer, and
an upper inorganic layer disposed on the organic layer.

13. The display device of claim 12, further comprising:
a filling layer between the thin film encapsulation layer and the second capping layer,
wherein the filling layer extends to the first coupling member.

14. A display device, comprising:
a substrate;
a light emitting element layer disposed on the substrate;
a counter substrate facing the substrate;
a low refractive layer disposed on a surface of the counter substrate;
a first capping layer disposed on a surface of the low refractive layer;
a second capping layer disposed on a surface of the first capping layer;
a spacer layer disposed on a surface of the second capping layer;
a first coupling member between the substrate and the counter substrate, and coupling the substrate to the counter substrate; and
a second coupling member disposed on side surfaces of the substrate and the counter substrate, and coupling the substrate to the counter substrate,
wherein at least one of the first capping layer and the second capping layer contains silicon oxynitride represented by Chemical Formula 1:
SiₓO_{y}N_{z} (30≤x≤40, 1≤y≤5, and 55≤z≤70), [Chemical Formula 1]
where the unit is atomic %.

15. The display device of claim 14, wherein
the first coupling member contains a first moisture absorbent, and
the first moisture absorbent is contained in an amount of 20% to 50% by weight with respect to a total weight of the first coupling member.

16. The display device of claim 14, wherein
the second coupling member contains a second moisture absorbent, and
the second moisture absorbent is contained in an amount of 20% to 50% by weight with respect to a total weight of the second coupling member.

17. The display device of claim 14, wherein
the second coupling member is spaced apart from the first coupling member, and
the second coupling member surrounds the first coupling member in plan view.

18. The display device of claim 17, wherein pores are between the first coupling member and the second coupling member.

19. The display device of claim 14, wherein
the spacer layer contains an organic material, and
the first coupling member extends to the spacer layer.

20. The display device of claim 14, wherein
the low refractive layer contains an organic material, and
the second coupling member is in contact with a side surface of the low refractive layer.
